(19) United States
(12) Patent Application Publication
(10) Pub. No.: US 2017/0040483 A1
(43) Pub. Date: Feb. 9, 2017

(54) CONCENTRATING SOLAR ENERGY SYSTEM WITH LIQUID FILLED LENS

(71) Applicant: SOLENSE LTD, Norwich, Norfolk (GB)

(72) Inventor: MIKE ROBINSON, Norwich, Norfolk (GB)

(73) Assignee: SOLENSE LIMITED, Norwich (GB)

(21) Appl. No.: 15/114,410

(22) PCT Filed: Jan. 28, 2014
(86) PCT No.: PCT/IB2014/058607

§ 371 Date: Jul. 27, 2016

(51) Int. Cl. H01L 31/054; F24J 2/08; H01L 31/052

(52) U.S. Cl. CPC H01L 31/0543; H01L 31/052; F24J 2/08

(57) ABSTRACT

A solar photovoltaic system including a liquid filled lens configured to concentrate sunlight for the generation of electricity, desalination of water or production of steam. The liquid lens and receiver are mounted on a tracker. The complete system is lightweight and modular with multiple configurations possible. The liquid lens is manufactured using an improved method.

The use of a liquid lens for the purpose of collecting solar energy is novel.

This patent refers to a system for the collection of solar energy by use of a concentrating lens. It also includes a manufacturing method for the lens.

### FIELD OF THE INVENTION

This invention has its field of application within the industry dedicated to the harnessing of solar energy by its concentration. More specifically, this invention is aimed at the section of the field concerned with reducing the cost of manufacturing and installation, and weight constraints.

### STATE OF THE ART

This invention relates to concentrating solar energy devices, particularly those of industrial scale for use in direct sunlight. These devices convert sunlight into electricity through the use of photovoltaic cells, typically made from semiconductor materials which may include gallium arsenide. Although non-concentrating photovoltaic system typically use single junction photovoltaic cells, systems which concentrate the insolation onto the photovoltaic cell typically use triple junction photovoltaic cells.

Other uses of concentrated sunlight include water desalination and steam production. In these cases the photovoltaic cell would be replaced by tubes carrying a working fluid of through some other mechanism.

Cost is the largest barrier to the large-scale role out of industrial scale photovoltaics. Although photovoltaic cell costs have been reduced greatly since their inception, overall system costs are not yet competitive with traditional power generation. Using a lens to concentrate light onto the photovoltaic cell reduces the number of cells required for a given surface area of insolation but requires direct irradiance. This invention will reduce both manufacturing and installation costs of the lens at the possible loss of some efficiency.

To date no large-scale commercial Concentrating Photovoltaic system has been constructed. There are no solar energy systems which use a liquid filled lens.

Current generation concentrating solar energy devices typically use parabolic mirrors or Fresnel lenses. These optics yield high concentrations and efficiencies in optical energy transmission but are expensive to manufacture and can be heavy. If used with photovoltaic cells they may also require complex heat sink arrangements to prevent thermal destruction of the cells.

A light guide is typically used to channel the insolation between the lens and the cell although this depends on the concentration arrangement.

In contrast, a concentrating lens comprised of two transparent thermoplastic parts and filled with liquid would be lightweight and allow for a reduction in the overall weight of the system. This lens would yield medium levels of concentration. Although efficiency may be lost compared to similar existing systems, the manufacturing and installation costs would be greatly reduced.

### BRIEF DESCRIPTION OF THE DRAWINGS

The drawings contain the following components:
1. Thermoplastic lens casing
2. Clamping flange
3. Light guide tube
4. Photovoltaic cell
5. PCB for electrical wiring of the photovoltaic cell
6. Heat sink
7. Thermoplastic lens casing (TOP)
8. Thermoplastic lens casing (BOTTOM)
9. O-ring
10. Light transmissive liquid
11. Bolt
12. Vessel

The drawings are for illustrative purposes only and not to scale. In particular the curvature of the lens surface may be varied to achieve optimal transmission of insolation.

FIG. 1 is an exploded perspective view of the lens, optional light guide tube, cell assembly and optional heatsink.

FIG. 2 is a plan view of FIG. 1 showing one possible bolting configuration.

FIG. 3 is a side view of FIG. 2 showing one possible lens housing and coupling flange configuration.

FIGS. 4-7 are exploded perspective views of part of one possible manufacturing process for the lens assembly.

### DESCRIPTION OF THE INVENTION

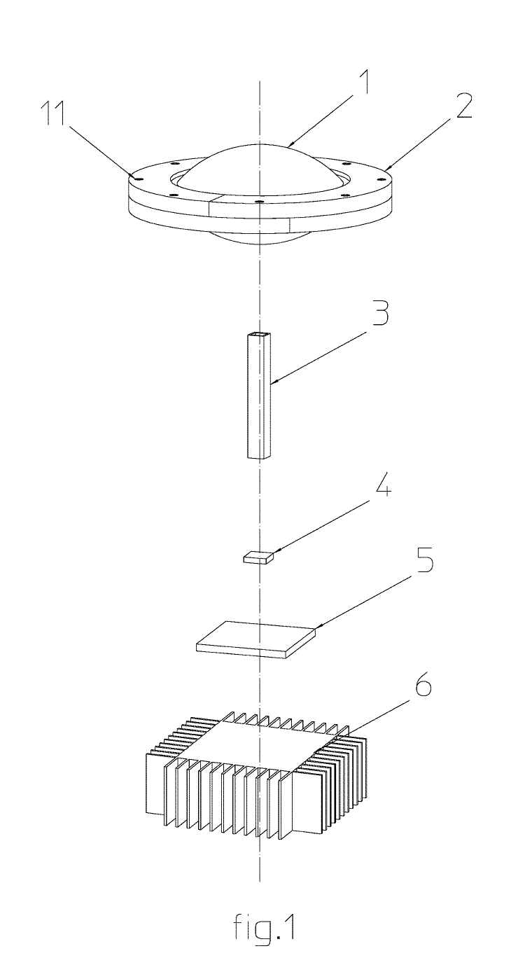

Referring to the drawings and FIG. 1 in particular, a liquid filled lens assembly is located above a light guide and photovoltaic cell. A frame may be used to hold the lens above the light guide and cell assembly.

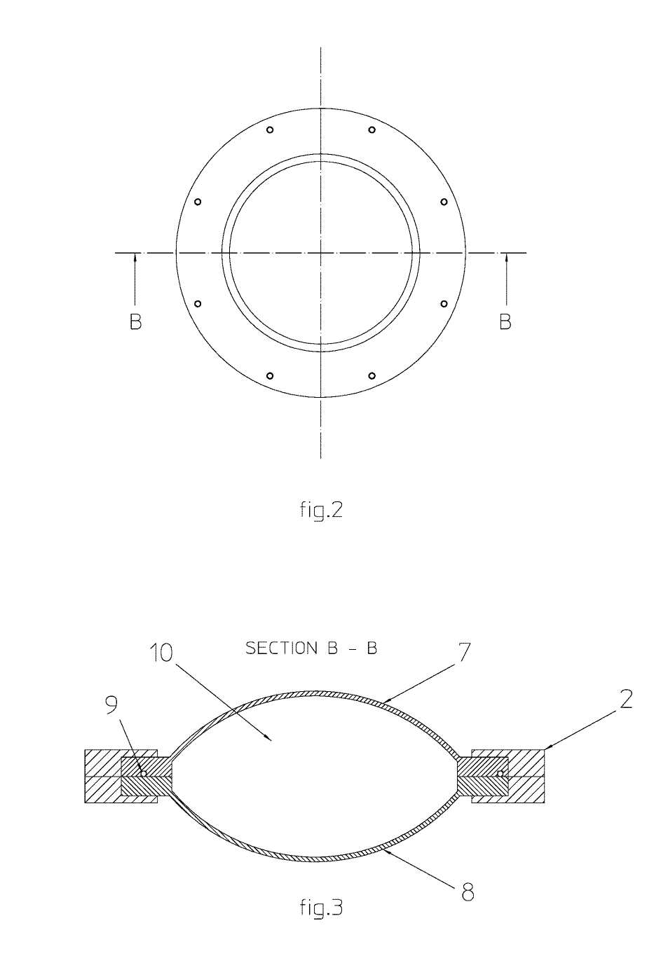

The lens shown in FIG. 3 is comprised of two transparent thermoplastic surfaces which contain a liquid.

The formula describing the curvature of the thermoplastic surfaces will be governed by a number of factors including the distance of between the lens and the cell assembly as well as the refractive index of the liquid contained within the lens. The two surfaces may be dissimilar in profile.

The liquid contained within the transparent thermoplastic surfaces may be glycerol or another light transmissive liquid.

The two thermoplastic surfaces may be held together by a flange incorporating an O-ring. This arrangement forms a seal between the two surfaces which keeps the liquid inside the lens. Other methods of sealing could be used, including ultrasonic welding or an adhesive.

The photovoltaic cell can either be a single or triple junction silicon or gallium arsenide photovoltaic cell.

The cell is mounted on a PCB to form a cell assembly which transfers the electricity generated by the photovoltaic cell away from the cell. Optionally, the cell assembly may be mounted on a heat sink which transfers excess heat away from the photovoltaic cell.

Multiple cells may be mounted onto a single PCB and multiple cells or PCBs may be serviced by a single modular heatsink.

The lens, light guide, photovoltaic cell and heatsink may be held in their respective locations by a mounting frame.

Multiple lens and cell assemblies may be connected by wiring to form an array. An array will be mounted on a dual axis tracker. The tracker will be programmed to orientate the lens such that the direct insolation received by the array is maximised.

Multiple arrays may be connected in a single solar farm until the desired rated power output is reached.

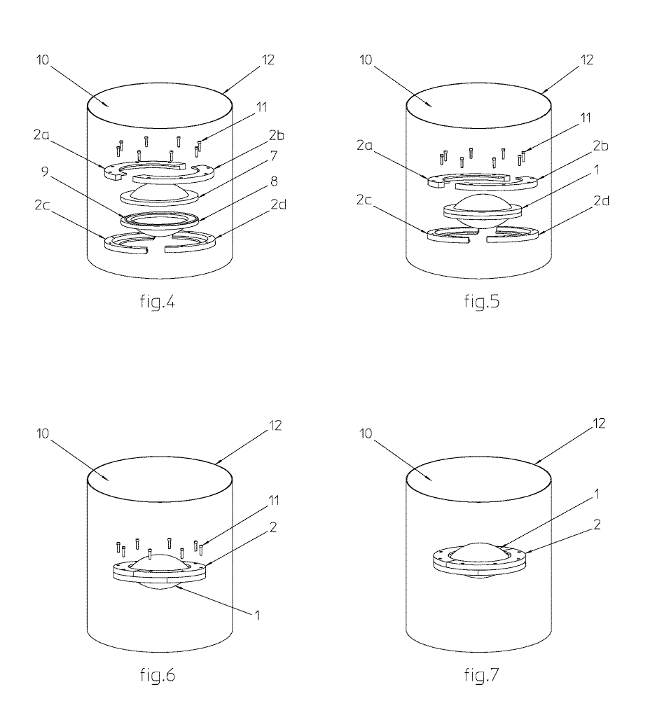

The lens may be manufactured using the following method:
1. As shown in FIG. 4 parts for the lens assembly are fully submerged within the liquid vessel (12).
2. As shown in FIG. 5 the two lens surfaces (7, 8) are brought together such that the liquid completely fills the lens assembly.
3. The flange sections (2a-d) and O-ring (9) are brought together such that they clamp either side of the lens assembly (1).
4. The bolts (11) are used to secure the flange assembly in place.
5. The complete lens assembly (1,2) is removed from the liquid vessel (12).

Optionally, welding, ultrasonic welding, adhesive or other joining techniques may be used in place of bolts for step 4.

1. A concentrating photovoltaic system comprising:
a. a liquid filled lens comprising;
i. two transparent thermoplastic surfaces;
ii. filled with liquid;
b. a photovoltaic cell positioned below the lens;
c. a frame having multiple structural elements supporting the lens and receiving device; and
d. a tracker system carrying the frame supporting the lens and receiving device and capable of orientating the lens to receive solar insolation.

2. The system of claim 1 wherein the liquid within the lens is glycerine.

3. The system of claim 1 wherein the two thermoplastic surfaces which form the lens contain multiple peaks and troughs such that one set of two surfaces may concentrate irradiance onto multiple photovoltaic cells.

4. The system of claim 1 wherein a light guide is positioned above the photovoltaic cell to direct insolation onto the photovoltaic cell.

5. A method for manufacturing a liquid filled lens, said method comprising:
a. Providing two interlocking transparent thermoplastic surfaces
b. Providing a vessel containing a liquid to be used as the filling between the two surfaces of sufficient volume to fully contain said interlocking surfaces
c. Subjecting said two interlocking surfaces to immersion in the liquid to such a depth that they are fully submerged
d. Bringing the two said interlocking surfaces together whilst they remain fully submerged
e. Securing the two said interlocking surfaces together whilst they remain submerged

6. The manufacturing method of claim 5 wherein weldments are used in place of the segmented flange and bolt arrangement of claim 5e.

7. The manufacturing method of claim 5 wherein ultrasonic weldments are used in place of the segmented flange and bolt arrangement of claim 5e.

8. The manufacturing method of claim 5 wherein adhesive is used in place of the segmented flange and bolt arrangement of claim 5e.

9. The system of claim 1 wherein multiple photovoltaic cells are located on a single PCB.

10. The system of claim 1 wherein multiple photovoltaic cells are serviced by a single heatsink.

11. The system of claim 1 wherein the system is mounted on a tracker capable of orientating the lens arrangement(s) such that they receive optimal irradiance.

12. The system of claim 1 wherein the two surfaces which make up the lens are manufactured from glass.

13. The system of claim 1 wherein a working fluid being carried by a tube is used in place of a photovoltaic cell for the purpose of steam generation or water desalination.
